(19) United States
(12) Patent Application Publication
(10) Pub. No.: US 2010/0330382 A1
(43) Pub. Date: Dec. 30, 2010

(54) BIAXIALLY ORIENTED POLYLACTIC ACID FILM WITH IMPROVED MOISTURE BARRIER

(75) Inventors: Shichen DOU, Warwick, RI (US); Keunsuk P. Chang, North Kingstown, RI (US)

Correspondence Address: MORRISON & FOERSTER LLP, 1650 TYSONS BOULEVARD, SUITE 400, MCLEAN, VA, 22102, US

(73) Assignee: TORAY PLASTICS (AMERICA), INC., N. Kingstown, RI (US)

(21) Appl. No.: 12/824,759

(22) Filed: Jun. 28, 2010

Related U.S. Application Data
(60) Provisional application No. 61/220,840, filed on Jun. 26, 2009.

(51) Int. Cl. B32B 15/08; B32B 27/08; B29C 47/06; C23C 16/00

(52) U.S. Cl. 428/457; 428/411.1; 264/173.16; 427/250

(57) ABSTRACT

A biaxially oriented multilayer film comprising a skin layer of polyhydroxyalkanoate, a core layer of polylactic acid polymer and a sealant layer with a metal deposited upon one surface of the skin layer of polyhydroxyalkanoate polymer. This metallized, polyhydroxyalkanoate-coextruded polylactic acid film exhibits improved moisture barrier property versus a metallized, non-polyhydroxyalkanoate-coextruded polylactic acid film.

### CROSS-REFERENCE TO RELATED APPLICATION

This application claims the benefit of U.S. Provisional Application Ser. No. 61/220,840, filed Jun. 26, 2009, the entirety of which is incorporated herein by reference.

### FIELD OF THE INVENTION

This invention relates to a multi-layer biaxially oriented polylactic acid (BOPLA) film with a novel formulation, which exhibits improved barrier properties, particularly for moisture vapor transmission barrier, after metallizing.

### BACKGROUND OF THE INVENTION

Biaxially oriented polypropylene (BOPP) films used for packaging, decorative, and label applications often perform multiple functions. In a lamination, they provide printability, transparent or matte appearance, or slip properties. The films sometimes provide a surface suitable for receiving organic or inorganic coatings for gas and moisture barrier properties. The films sometimes provide a heat sealable layer for bag forming and sealing, or a layer that is suitable for receiving an adhesive either by coating or by laminating.

However, in recent years, interest in “greener” packaging has been strongly developing. Interest in packaging materials based on biologically derived polymers is increasing due to concerns with non-renewable resources, waste production, raw materials, and the production of greenhouse gases. Biodegradable polymers would alleviate the growing environmental problem attributable to the production of an excessive amount of plastic waste. Non-biodegradable plastic waste requires years to decompose and includes an ever-increasing volume fraction of the waste present in landfills. In addition, it is believed that bio-based polymers, once fully scaled up, will help reduce reliance on petroleum and thereby reduce the production of greenhouse gases due in part to their biodegradability.

Bio-based polymers such as polylactic acid, which is derived from corn starch and thus can be considered to be derived from a renewable resource, is one of the more popular and commercially available materials available for packaging film applications. However, due to the higher commercial expenses compared to traditional polymers and the difficulties that can arise in the processing of these bio-polymers to form a product comparable to or matching that of existing products, there has been little commercial success. Many compositions involving these polymers exhibit limited quality, processability, degradability, or some combination thereof.

U.S. Pat. No. 7,128,969 describes a film composed of a base layer of PLA with a minority component of a thermoplastic or polyolefin such as polypropylene or polyethylene, typically including less than 1% by weight of the base layer. Such a formulation is particularly suitable for thermoforming or biaxial stretching by means of pneumatic drawing or other mechanical forming. However, the patent does not contemplate such a structure or formulation for metallizing or for high barrier applications. Nor does it contemplate multi-layer film designs utilizing polyolefin-based metal receiving layers wherein the majority component of such a layer is polyolefin and not PLA.

U.S. Pat. No. 7,678,444 describes a film including a core layer of PLA, PHA, or another renewable polymer, with a layer composed of a heat-resistant polymer, such as polypropylene, substantially surrounding this core layer. Such a formulation is particularly suitable for the transport or storage of PLA through or in hot areas where a high temperature may cause PLA without such an outer layer to deform due to heat. However, the patent does not contemplate such a formulation with an outer PHA skin layer, nor does it contemplate metallization of such a film with superior gas and moisture barrier properties, nor such a film with a biodegradable, metal receiving layer.

EP Patent No. 01385899 describes a multi-layer film design using a PLA base layer formulated with a cyclic polyolefin copolymer (COC) as a cavitating agent to produce an opaque, biaxially oriented PLA film. However, this patent does not contemplate metallization of such a film with superior gas and moisture barrier properties, nor such a film with a degradable, non-PLA metal receiving layer.

EP Patent No. 01385700 describes a biaxially oriented PLA film with good antistatic properties by incorporating antistatic additives such as glycerol monostearate (GMS) into the base layer of PLA. However, the patent does not contemplate such a structure or formulation for metallizing or for high barrier applications. Nor does it contemplate multi-layer film designs utilizing polyolefin-based metal receiving layers wherein the majority component of such a layer is polyolefin and not PLA.

U.S. patent application Ser. No. 12/332,153 describes multi-layer PLA film made with a metal receiving layer of a polyolefin combined with a tie resin or compatibilizing resin or coextruded with a discrete tie resin layer, which is coextruded with a PLA core layer. This polyolefin metal receiving layer can improve moisture barrier properties after metallization. However, such a hybrid structure would not be 100% bio-polymer and sustainably sourced from renewable resources.

### SUMMARY OF THE INVENTION

The above issues of making high gas and moisture barrier metallized OPLA films are addressed. The inventors have found a solution that uses a combination of bio-based polymers from renewable resources for improved metallized barrier properties, particularly moisture vapor barrier. The solution involves the use of a PLA base layer coextruded with a polyhydroxyalkanoate (PHA) skin layer, which is an alternative biopolymer that inherently has better moisture barrier and moisture resistance than PLA. It can also be contemplated to extrude a PHA film layer alone and metallize this structure for a significant improvement in gas barrier properties, particularly for moisture barrier.

One embodiment is a multi-layer biaxially oriented film including a first layer (A) of a PHA-based resin; a second layer (B) including a substantially crystalline PLA resin-containing blend on one side of said sealable amorphous PLA layer; and a third layer (C) including a heat sealable resin comprised of a substantially amorphous PLA resin and an optional modifying resin to improve heat seal initiation. The PHA skin layer (A) includes PHA and may also include blends with either amorphous or crystalline PLA or a derivative thereof, preferably PHA or a derivative thereof, or blends thereof wherein the PHA is present at greater than 20 wt %. This layer can also incorporate the various inorganic antiblock particles of suitable size, selected from the group comprising of amorphous silicas, aluminosilicates, sodium calcium aluminum silicates, crosslinked silicone polymers, and/or polymethylmethacrylates to act as antiblocks for film handling or machinability. Suitable amounts range from 0.01-0.5% by weight of the skin layer and typical particle sizes of 2.0-6.0 μm in diameter. Preferably, amounts will be about 0.03-0.06 wt % of the skin layer and particle size preferably 3.0 μm nominal diameter.

The second crystalline PLA resin-containing blend layer (B) could be considered a core or base layer to provide the bulk strength of the laminate film. The second PLA core layer (B) is includes a crystalline PLA homopolymer, which may be combined with an optional amount of ethylene-acrylate copolymer that acts as a processing aid to enable high transverse orientation rates of 8-11×. The second PLA core layer (B) may also include an optional amount of amorphous PLA blended with the crystalline PLA. The second PLA core layer (B) can also include inorganic antiblock particles of suitable size. These particles may include, for example, amorphous silicas, aluminosilicates, sodium calcium aluminum silicates, crosslinked silicone polymers, and/or polymethylmethacrylates to act as antiblocks for film handling or machinability. Suitable amounts range from 0.03-0.5% by weight of the core layer and typical particle sizes of 2.0-6.0 μm in diameter. If so desired, cavitating agents may be added to the core layer (B) such that upon biaxial orientation, voids are formed within this layer, thus rendering the film a matte or opaque and often, pearlescent white appearance. Such cavitating agents may be inorganic particles such as calcium carbonate, talc, or other minerals; or polymeric cavitating agents such as polystyrene, cyclic olefin copolymer, or other polymers. Titanium oxides may also be incorporated with the cavitating agent to provide a brighter white appearance.

Preferably, the second PLA resin-containing core layer (B) comprises a crystalline polylactic acid homopolymer of about 90-100 wt % L-lactic acid units (or 0-10 wt % D-lactic acid units). An optional amount of amorphous PLA may also be blended in with the crystalline PLA from 0-48 wt % of the core layer. The amorphous PLA is also based on L-lactic acid units but has greater than 10 wt % D-lactic acid units and/or meso-lactide units (which includes one each of L and D lactic acid residuals). An optional amount of ethylene-acrylate copolymer can also be added to the core layer at about 2-10 wt % of the core layer as a process aid for orientation, particularly transverse orientation. Migratory slip additives may also be contemplated to control COF properties such as fatty amides (e.g. erucamide, stearamide, oleamide, etc.) or silicone oils ranging from low molecular weight oils to ultra high molecular weight gels. Suitable amounts of slip additives to use can range from 300 ppm to 10,000 ppm of the layer.

The PLA heat sealable resin-containing layer (C) is composed substantially of an amorphous PLA of greater than 10 wt % D-lactic acid units. It is not necessary to use any of the impact modifier/process aid ethylene-acrylate copolymer in this case, as the amorphous PLA resin blend can be oriented relatively easily. Optionally, this heat sealable layer can also contain modifiers to improve further the heat seal initiation and range. Preferably, such modifiers can be minority amounts of polycaprolactone (PCL) or poly(butylene adipate-co-butylene terephthalate) (PBAT). This third heat sealable amorphous PLA resin-containing layer (C) can also include an antiblock component, for example, amorphous silicas, aluminosilicates, sodium calcium aluminum silicates, crosslinked silicone polymers, and polymethylmethacrylates to aid in machinability and winding and to lower coefficient of friction (COF) properties. Suitable amounts range from 0.3-0.5% by weight of the heat sealable layer and typical particle sizes of 2.0-6.0 μm in diameter, depending on the final thickness of this layer. Migratory slip additives may also be contemplated to control COF properties such as fatty amides (e.g. erucamide, stearamide, oleamide, etc.) or silicone oils ranging from low molecular weight oils to ultra high molecular weight gels. Suitable amounts of slip additives to use can range from 300 ppm to 10,000 ppm of the layer.

In one embodiment of a three-layer coextruded film structure, the skin layer (A) can include similar amounts of antiblock and slip additives as the respective core and heat sealable layers, although the amounts are likely to be optimized for performance. In this embodiment, it is not necessary for the core layer (B) to include antiblock particles (although migratory additives may still be included in the core layer as a reservoir from which such additives may migrate to the outer surface layers as desired).

In the case where the above embodiments are to be used as a substrate for vacuum deposition metallizing, it is recommended that migratory slip additives not be used, as these types of materials may adversely affect the metal adhesion or metallized gas barrier properties of the metallized BOPLA film. It is thought that as the hot metal vapor condenses on the film substrate, such fatty amides or silicone oils on the surface of the film could vaporize and cause pin-holing of the metal-deposited layer, thus compromising gas barrier properties. Thus, only non-migratory antiblock materials should be used to control COF and web-handling.

For these multi-layer film structures described above, it is preferable to discharge-treat the exposed side of the first PHA-resin containing layer (A) of this multi-layer film structure, which is opposite the side contiguous with the core layer (B) for lamination, metallizing, printing, or coating. In this case, it is preferable to discharge-treat the side of the first layer (A) which is contiguous to the side of the core layer (B) opposite the heat sealable third layer (C). This first layer (A) is often formulated with materials that are conducive to receiving printing inks, metallizing, adhesives, or coatings, in this case, a PHA-containing resin.

Discharge-treatment in the above embodiments can be accomplished by several means, including but not limited to corona, flame, plasma, or corona in a controlled atmosphere of selected gases. Preferably, in one variation, the discharge-treated surface has a corona discharge-treated surface formed in an atmosphere of CO₂ and N₂ to the exclusion of O₂.

Preferably, the laminate film is produced via coextrusion of the heat sealable layer, the blended core layer, and the metal-receiving PHA-containing skin layer through a compositing die whereupon the molten multilayer film structure is quenched upon a chilled casting roll system or casting roll and water bath system and subsequently oriented in the machine and/or transverse direction into an oriented multi-layer film. Machine direction orientation rate is typically 2.0-3.0× and transverse direction orientation—with the use of the ethylene-acrylate impact modifier process aid—is typically 8.0-11.0×. Otherwise, without the ethylene-acrylate impact modifer process aid, transverse direction orientation may be limited to a lower rate, typically 3.0-6.0×. Heat setting conditions in the TDO oven is also critical to minimize thermal shrinkage effects.

In one embodiment, multi-layer BOPLA film was made using a 1.5 m wide pilot line sequential orientation process with a blend of 85 wt % Natureworks PLA4032D and 15 wt % Natureworks PLA4060D as core layer (B), one sealant layer (C) of substantially Natureworks PLA4060D with an amount of Silton JC30 3 μm spherical silicate antiblock at about 3000 ppm loading of the (C) layer, and a metal receiving skin layer (A) of various PHA-containing formulations as will be defined in the examples, via coextrusion through a die, cast on a chill drum using an electrostatic pinner, oriented in the machine direction through a series of heated and differentially sped rolls, followed by transverse direction stretching in a tenter oven. The multilayer coextruded laminate sheet is coextruded at processing temperatures of ca. 190° C. to 205° C. through a die and cast onto a cooling drum whose surface temperature is controlled between 15° C. and 26° C. to solidify the non-oriented laminate sheet at a casting speed of about 6 mpm. The non-oriented laminate sheet is stretched in the longitudinal direction at about 55° C. to 65° C. at a stretching ratio of about 3 to about 4 times the original length. The resulting stretched sheet is annealed at about 40° C. to 45° C. and cooled at about 30° C. to 40° C. to obtain a uniaxially oriented laminate sheet. The uniaxially oriented laminate sheet is introduced into a tenter at a linespeed of ca. 18 to 50 mpm and preliminarily heated between about 65° C. and 75° C., and stretched in the transverse direction at about 75° C. to 90° C. at a stretching ratio of about 4 to about 8 times the original length and then heat-set or annealed at about 90° C. to 95° C. with the exit rails set for a 5% relaxation to reduce internal stresses due to the orientation and minimize shrinkage and give a relatively thermally stable biaxially oriented sheet.

A preferred embodiment is to use the multi-layer heat sealable film as a metallizing film via vapor-deposition, preferably a vapor-deposited aluminum layer, with an optical density of at least about 1.5, preferably with an optical density of about 2.0 to 4.0, and even more preferably between 2.3 and 3.2. Preferably, the skin layer (A) should be metallized due to its better metal adhesion, metal gloss, and gas barrier properties. Additionally, this layer's surface may also be modified with a discharge treatment to make it suitable for metallizing, laminating, printing, or converter applied adhesives or other coatings.

A method to allow the production of improved moisture barrier and moisture resistance BOPLA films using degradable and compostable modifiers is provided. Such a film method and composition can result in faster packaging speeds with less distortion issues while maintaining attractive appearance, compostability, and cost.

Additional advantages will become readily apparent to those skilled in the art from the following detailed description, wherein only the preferred embodiments of this are shown and described, simply by way of illustration of the best mode contemplated for carrying out this invention. As will be realized, this invention is capable of other and different embodiments, and its details are capable of modifications in various obvious respects, all without departing from this invention. Accordingly, the examples and description are to be regarded as illustrative in nature and not as restrictive.

### DETAILED DESCRIPTION OF THE INVENTION

Multi-layer biaxially oriented polylactic acid (BOPLA) films with a novel formulation are described. The films exhibit improved barrier properties, particularly for moisture vapor transmission barrier, after metallizing. This high barrier formulation combines a polyhydroxyalkanoate (PHA)-based metal receiving layer coextruded with a PLA core layer to improve metallized moisture and oxygen barrier as well as metal adhesion.

For bio-based polymers such as PLA to be fit-for-use for many snack food packaging applications, it is desirable that the bio-based polymer film match as many of the attributes as possible of BOPP films, and therefore exhibit the level of quality, that BOPP is well-known for such as heat sealability, printability, controlled COF, metallizability, barrier, etc. In particular, for high barrier packaging, metallized oriented PLA films should demonstrate good oxygen and moisture barrier properties. For metallized oriented PLA in particular, a high oxygen barrier property is generally easily achieved due to the polar nature of PLA, which provides good hydrogen-bonding of the polymer molecules. However, this polar nature tends to be detrimental for achieving high moisture barrier.

Many products currently on the market do not provide satisfactory moisture barrier properties. For example, Celplast Metallized Products, Ltd.'s Enviromet™ high barrier metallized PLA film data sheet describes a product that exhibits an excellent oxygen barrier of 6.2 cc/m²/day (at 23° C., 50% relative humidity or RH) but a relatively poor moisture barrier of 3.1 g/m²/day (at 38° C., 90% RH) as compared to typical metallized biaxially oriented polypropylene films. (High barrier metallized BOPP such as Toray Plastics (America), Inc.'s PWX3 product typically demonstrates oxygen barrier of 15.5 cc/m²/day (23° C., 0% RH) and moisture barrier of 0.155 g/m²/day (38° C., 90% RH).)

Another manufacturer of barrier PLA film, Alcan Packaging Inc., produces a silicon oxide coated PLA film under the tradename Ceramis® whose typical data sheet shows an oxygen barrier of 7.75 cc/m²/day (23° C., 50% RH) and moisture barrier of 7.75 g/m²/day (38° C., 90% RH). Biofilm S. A. promotional literature (such as presented at the “Innovation Takes Root” conference hosted by NatureWorks LLC at Las Vegas, Nev. Sep. 16-18, 2008) discusses transparent barrier PLA films demonstrating moisture barrier of 3-10 g/m²/day (38° C./90% RH) using various vacuum chamber deposition processes. For both the latter transparent barrier PLA films, it is possible to contemplate vacuum deposition of metal such as aluminum on top of the transparent barrier layer (e.g. silicon oxide, aluminum oxide, or other coatings) to improve moisture barrier properties, but such a product is likely to be costly due to the multiple processing steps required to metallize these films.

While one could employ traditional polymers exhibiting good moisture barrier properties as an outer layer to improve the effectiveness of this barrier and thereby the quality of the product, such incorporation could affect bio-degradability. To retain bio-degradability and moisture barrier quality, an additional component that is suitable, degradable and commercially reasonable must be used. The challenge with high moisture barrier properties and bio-degradable polymers like PLA may lie with the polar nature of these bio-degradable polymers. Without being bound by any theory, the thought is that water molecules—being polar themselves—may more easily migrate through a polar polymer film than a non-polar polymer film. In addition, it is known that there are alternative bio-polymers that can also be biodegradable and be produced from renewable resources. One such bio-polymer is polyhydroxyalkanoate (PHA) and its derivatives and copolymers (such as polyhydroxybutyrate (PHB) or poly-3-hydroxybutyrate-co-3-hydroxyvalerate (PHBV)). These thermoplastic linear polyester resins are produced from biological processes via bacterial fermentation of sugars or lipids. These micro-organisms exist in nature and feedstock sugars can come from renewable plant sources. PHAs can be processed in conventional extrusion equipment and generally have a lower Tg than PLA. Thus, they are more flexible and less brittle than PLA at room temperature. PHAs—and particularly PHBs—are also more resistant to moisture and less prone to hydrolytic degradation than PLAs. Literature sources show that PHA also has significantly better moisture barrier properties than those of PLA (Table 1, excerpted and adapted from Prof. Luc Averous, Univ. of Strasbourg, France, www.biodeg.net “Bioplastics Part 1,” copyright May 2009):

TABLE 1

| | | PHBV | PCL | PEA | PBSA | PBAT |
|---|---|---|---|---|---|---|
| | PLA | Monsanto | Solway | Bayer | Showa | Eastman |
| | Dow-Cargill | (Biopol D400G) | (CAPA | (BAK | (Bionolle | (eastar bio |
| | (NatureWorks) | HV = 7 mol % | 680) | 1095) | 3000) | 14766) |
| Density | 1.25 | 1.25 | 1.11 | 1.07 | 1.23 | 1.21 |
| Melting point, in ° C. | 152 | 153 | 65 | 112 | 114 | 110-115 |
| (DSC) | | | | | | |
| Glass transition, in ° C. | 58 | 5 | −61 | −29 | −45 | −30 |
| (DSC) | | | | | | |
| Crystallinity (in %) | 0-1 | 51 | 67 | 33 | 41 | 20-35 |
| Modulus, in MPa (NFT | 2050 | 900 | 190 | 262 | 249 | 52 |
| 51-035) | | | | | | |
| Elongation at break, in % | 9 | 15 | >500 | 420 | >500 | >500 |
| (NFT 51-035) | | | | | | |
| Tensile stress at break or | — | — | 14 | 17 | 19 | 9 |
| max., in MPa (NFT 51-035) | | | | | | |
| Biodegradation* | 100 | 100 | 100 | 100 | 90 | 100 |
| Mineralization in % | | | | | | |
| Water permeability | 172 | 21 | 177 | 680 | 330 | 550 |
| WVTR at 25° C. | | | | | | |
| (g/m2/day) | | | | | | |
| Surface tension** | 50 | — | 51 | 59 | 56 | 53 |
| (g) in mN/m. | | | | | | |
| gd (Dispersive component) | 37 | — | 41 | 37 | 43 | 43 |
| gp (Polar component) | 13 | — | 11 | 22 | 14 | 11 |

| | | PHBV (PHA) | | PEA | PBSA | |
|---|---|---|---|---|---|---|
| | PLA | Enmat | PCL | Bayer | Showa | PBAT |
| | Dow-Cargill | Metabolix | Perstop | (BAK | (Bionolle | BASF |
| | (NatureWorks) | (HV = 7 mol %) | (CAPA6800) | 1095) | 3000) | (Ecoflex 7011) |
| Density. | 1.25 | 1.25 | 1.11 | 1.07 | 1.23 | 1.21 |
| Melting point, in ° C. (DSC) | 152 | 153 | 65 | 112 | 114 | 110-115 |
| Glass transition, in ° C. (DSC) | 58 | 5 | −61 | −29 | −45 | −30 |
| Cristallinity (in %) | 40 | 51 | 67 | 33 | 41 | 20-35 |
| Modulus, in MPa (NFT 51-035) | 2050 | 900 | 190 | 262 | 249 | 52 |
| Elongation at break, in % | 9 | 15 | >500 | 420 | >500 | >500 |
| (NFT 51-035) | | | | | | |
| Tensile stress at break or | — | — | 14 | 17 | 19 | 9 |
| max., in MPa (NFT 51-035) | | | | | | |
| Biodegradation* | 100 | 100 | 100 | 100 | 90 | 100 |
| Mineralization in % | | | | | | |
| Water permeability | 172 | 21 | 177 | 680 | 330 | 550 |
| WVTR at 25° C. | | | | | | |
| (g/m2/day) | | | | | | |
| Surface tension** | 50 | — | 51 | 59 | 56 | 53 |
| (g) in mN/m. | | | | | | |
| gd (Dispersive component) | 37 | — | 41 | 37 | 43 | 43 |
| gp (Polar component) | 13 | — | 11 | 22 | 14 | 11 |

*At 60 days in controlled composting according to ASTM 5336.
**Determinations from contact angles measurements of probes liquids

Table 1 indicates the moisture barrier of PHA is 21 g/m²/day compared to 172 g/m²/day for PLA. Other literature sources show similar comparative data between PHA and PLA, with PHA generally having significantly improved moisture barrier compared to PLA. Thus, if one were to metallize a PHA-based surface, the moisture barrier properties of such a construction could be significantly improved. If such a PHA-based metal receiving layer was coextruded as a contiguous layer with a PLA-based core layer, this could significantly improve the moisture barrier property of a substantially PLA-based film while maintaining biodegradability.

Provided are methods and films that achieve high moisture barrier properties with metallized OPLA films while simultaneously incorporating sustainable, bio-based resin content, and maintaining degradable properties, as well as maintaining a reasonable economical process. The inventors have found a solution whereby a multilayer film design incorporates a polylactic acid base layer coextruded with a polyhydroxyalkanoate skin layer that is then coated with aluminum via vapor deposition metallization. This film structure provides improved moisture barrier properties, maintains a majority composition of bio-polymer in the total film construction (ca. 95 wt % or more), and is degradable under biodegradation or composting environmental conditions.

In order to sufficiently protect snack food products from staleness and/or rancidity, and to ensure a reasonably adequate shelf-life, the metzillized films described herein may have a moisture barrier property of at least about 1.0 g/m²/day or better, and more preferably, have a moisture barrier property of about 0.50 g/m²/day or better, at 38° C. and 90% RH. These films may have an oxygen barrier of at least about 46.5 cc/m²/day, and more preferably 31 cc/m²/day or better, at 23° C. and 0% RH.

In one embodiment, the laminate film includes a three-layer biaxially oriented coextruded film of a metal-receiving skin layer (A) including a polyhydroxyalkanoate polymer (PHA), optionally blended with an amount of an amorphous or crystalline polylactic acid polymer (PLA), a PLA resin core layer (B) including a crystalline polylactic acid polymer, optionally blended with an amount of an amorphous PLA polymer and/or an amount of ethylene-acrylate copolymer; and a heat sealable layer (C) including an amorphous polylactic acid polymer and optionally an amount of poly(butylene adipate-co-butylene terephthalate) (PBAT) copolymer, or polycaproplactone (PCL), or blends thereof. The skin layer (A) may be discharge-treated.

The polyhydroxyalkanoate skin layer (A) is a crystalline polyhydroxyalkanoate of a specific form and can be biaxially oriented. The family of polyhydroxyalkanoates includes mainly the homopolymer polyhydroxybutyrate (PHB) and different copolyesters in the forms of polyhydroxybutyrate co-hydroxyalkanoates, such as polyhydroxybutyrate co-hydroxyvalerate (PHBV) or polyhydroxybutyrate co-hydroxyoctonoate. Suitable examples of these resins for this can be obtained from Tianan Biologic Materials, Inc., such as Enmat® 5010P from Metabolix Mirel® and from Danimer Scientific-Meredian. Enmat® 5010P is a poly(3-hydroxy-butyrate-co-3-hydroxyvalerate) resin with Vicat softening temperature of about 143° C., melting point of about 167° C., a crystallization temperature of about 109° C., and density of about 1.25 g/cm³. Metabolix Mirel® is a polyhydroxybutyrate resin with a Vicat softening temperature of about 133° C., melting point of about 150-160° C., and density of about 1.4 g/cm³. Danimer Scientific-Meredian is a polyhydroxyalkanoate resin. PHAs, specifically PHBs, are water insoluble and relatively resistant to hydrolytic degradation. Most other bioplastics are water-sensitive, and so this PHA-based skin layer serves to substantially improve moisture barrier properties of the film while maintaining biodegradability.

The skin layer (A) can be coextruded on either side of the core layer, said skin layer having a thickness after biaxial orientation of between 0.5 and 5 μm, preferably between 1.0 and 2.0 μm, and more preferably, about 1.0 μm. The coextrusion process includes a three-layered compositing die, which is used to sandwich the core layer between the heat sealable resin layer and the skin layer (A). This skin layer may also advantageously contain an anti-blocking agent and/or slip additives for good machinability and a low coefficient of friction in about 0.01-0.5% by weight of the layer, preferably about 250-1000 ppm, and more preferably about 300-600 ppm. Particularly preferred is the use of a spherical nominal 3 μm sodium calcium aluminum silicate such as Mizusawa Industrial Chemical Co. Silton® JC30 brand at about 300 ppm of the layer (A).

Preferably, non-migratory inorganic slip and/or antiblock additives as described previously should be used to maintain gas barrier properties and metal adhesion if metallizing, or ink wetting and ink adhesion if printing. Additionally, in this embodiment of a coextruded multilayer film, the skin layer (A) can be treated with either an electrical corona-discharge treatment method, flame treatment, atmospheric plasma, or corona discharge in a controlled atmosphere of nitrogen, carbon dioxide, or a mixture thereof, with oxygen excluded and its presence minimized. The latter method of corona treatment in a controlled atmosphere of a mixture of nitrogen and carbon dioxide is particularly preferred. This method results in a treated surface that comprises nitrogen-bearing functional groups, preferably at least 0.3 atomic % or more, and more preferably, at least 0.5 atomic % or more. This treated skin layer is then well suited for subsequent purposes of metallizing, printing, coating, or laminating, the preferable embodiment being for metallizing.

The polylactic acid resin core layer (B) is a crystalline polylactic acid of a specific optical isomer content and can be biaxially oriented. As described in U.S. Pat. No. 6,005,068, lactic acid has two optical isomers: L-lactic acid (also known as (S)-lactic acid) and D-lactic acid (also known as (R)-lactic acid). Three forms of lactide can be derived from these lactic acid isomers: L,L-lactide (also known as L-lactide) and which comprises two L-lactic acid residuals; D,D-lactide (also known as D-lactide) and which comprises two D-lactic acid residuals; and meso-lactide which comprises one each of L and D-lactic acid residuals. The degree of crystallinity is determined by relatively long sequences of a particular residual, either long sequences of L or of D-lactic acid. The length of interrupting sequences is important for establishing the degree of crystallinity (or amorphous) and other polymer features such as crystallization rate, melting point, or melt processability. The crystalline polylactic acid resin is preferably one comprised primarily of the L-lactide isomer with minority amounts of either D-lactide or meso-lactide or combinations of D-lactide and meso-lactide. Preferably, the minority amount is D-lactide and the amount of D-lactide is 10 wt % or less of the crystalline PLA polymer. More preferably, the amount of D-lactide is less than about 5 wt %, and even more preferably, less than about 2 wt %. A suitable example of crystalline PLA is 4032D. This resin has relative viscosity of about 4, a melting point of about 165-173° C., a crystallization temperature of about 100-120° C., a glass transition temperature of about 55-62° C., a D-lactide content of about 4.25 wt %, density of about 1.25 g/cm³, and a maximum residual lactide in the polylactide polymer of about 0.30% as determined by gas chromotography. Molecular weight M_{w} is typically about 200,000; Mₙ typically about 100,000; polydispersity about 2.0. Natureworks® 4032D is the preferred crystalline PLA resin, being more crystalline than other similar resins and more suitable for high heat biaxial orientation conditions.

The core resin layer (B) is typically 8 μm to 100 μm in thickness after biaxial orientation, preferably between 10 μm and 50 μm, and more preferably between about 15 μm and 25 μm in thickness. A preferred embodiment is to use the higher crystalline, higher L-lactide content PLA (lower wt % D-lactide of about 1.40) such as Natureworks® 4032D.

The core layer can also optionally include an amount of amorphous PLA resin to improve further extrusion processing and oriented film processing. The addition of amorphous PLA in the core layer helps to lower extrusion polymer pressure and, in terms of film manufacturing, helps to reduce or slow crystallization rate of the newly oriented film. This aids in the orientation of the PLA film in both machine and transverse directions and helps reduce defects such as uneven stretch marks. It also helps with the slitting of the biaxially oriented film at the edge-trimming section of the line by reducing the brittleness of the edge trim and reducing the instances of edge trim breaks which can be an obstacle to good productivity. The amorphous PLA is preferably based on a L-lactide isomer with D-lactide content of greater than 10 wt %. A suitable amorphous PLA to use is Natureworks® Ingeo™ 4060D grade. This resin has a relative viscosity of about 3.25-3.75, T_{g} of about 52-58° C., melting point approximately 148° C., heat seal initiation temperature of about 93° C., density of about 1.24 g/cm³, a D-lactide content of about 12 wt %, and a maximum residual lactide in the polylactide polymer of about 0.30% as determined by gas chromotography. Molecular weight M_{w} is about 180,000. Suitable amounts of amorphous PLA to use in the core are concentrations of up to about 48 wt % of the core layer, preferably up to about 30 wt % of the core layer, and even more preferably about 15-20 wt % of the core layer. It should be noted, however, that too much amorphous PLA in the core layer (e.g. 50% or greater) can cause high thermal shrinkage rates after biaxial orientation and in spite of heat-setting conditions in the transverse orientation oven to make a thermally stable film. A thermally, dimensionally stable film is important if the substrate is to be used as a metallizing, printing, coating, or laminating substrate. (However, if the BOPLA is desired as a shrinkable film, this composition and appropriate processing conditions might be suitable.)

An optional component of the core layer (B) is blending into the core layer a minority amount of ethylene-acrylate copolymer as a processing aid in orientation, in particular, to enable high transverse orientation rates (TDX) similar to that used in BOPP orientation (e.g. 8-10 TDX). Ethylene-acrylates are of the general chemical formula of CH₂═C(R¹)CO₂R² where R¹ can be hydrogen or an alkyl group of 1-8 carbon atoms and R² is an alkyl group of 1-8 carbon atoms. Ethylene-acrylate copolymers can be based on ethylene-acrylate, ethylene-methacrylate, ethylene-n-butyl acrylate-glycidyl methacrylate, ethylene-glycidyl methacrylate, ethylene-butyl-acrylate, ethylene acrylic esters, or blends thereof. Ethylene vinyl acetate (EVA) and ethylene methacrylate (EMA) can also be contemplated. Other similar materials may also be contemplated. As described in U.S. Pat. No. 7,354,973, suitable compositions of the ethylene-acrylate copolymers can be about 20-95 wt % ethylene content copolymerized with about 3-70 wt % n-butyl acrylate and about 0.5-25 wt % glycidyl methacrylate monomers. A particularly suitable ethylene-acrylate copolymer of this type is one produced by E. I. DuPont de Nemours and Company Packaging and Industrial Polymers Biomax® Strong 120. This additive has a density of about 0.94 g/cm³, a melt flow rate of about 12 g/10 minutes at 190° C./2.16 kg weight, a melting point of about 72° C., and a glass transition temperature of about −55° C. Other suitable ethylene-acrylate copolymer impact modifiers commercially available are: Dupont Elvaloy® PTW, Rohm & Haas, Inc. BPM500, and Arkema, Inc. Biostrength® 130.

Suitable amounts of ethylene-acrylate copolymer to be blended in the crystalline PLA-comprising core layer is from 2-10 wt % of the core layer, preferably 2-7 wt % and more preferably, 2-4 wt %. At these concentrations, acceptable clarity of the biaxially oriented film is maintained as well as compostability properties. Too much ethylene-acrylate may cause haziness; too little may not enable transverse orientation at 8-10×. Blending into the core layer can be done most economically by dry-blending the respective resin pellets; it is contemplated that more aggressive blending such as melt-compounding via single-screw or twin-screw can result in better dispersion of the ethylene-acrylate copolymer throughout the PLA matrix. The addition of Biomax 120 helps reduce internal stresses during orientation, particularly transverse orientation. The use of this processing aid can enable transverse orientation rates in excess of 4-5 TDX up to 7 to 10 TDX has been achieved. By using this processing aid, it is possible to improve productivity of making oriented PLA films at high transverse orientation rates (greater than 5 TDX).

The coextruded sealant layer (C) is a heat sealable resin layer comprised of an amorphous polylactic acid polymer and a modifying polymer. As described earlier, the amorphous PLA is preferably based on an L-lactide isomer with D-lactide content of greater than 10 wt %. A suitable amorphous PLA to use is Natureworks® Ingeo™ 4060D grade. This resin has a relative viscosity of about 3.25-3.75, T_{g} of about 52-58° C., melting temperature of approximately 148° C., heat seal initiation temperature of about 93° C., density of about 1.24 g/cm³, a D-lactide content of about 12 wt %, and a maximum residual lactide in the polylactide polymer of about 0.30% as determined by gas chromotography. Molecular weight M_{w} is about 180,000. The amount to be used in the heat sealable skin layer is about 50-99 wt % of the layer, preferably 70-95 wt %, and more preferably 85-90 wt %. The sealable skin layer (C) which is comprised substantially of Natureworks PLA4060D, can also optionally include an amount of antiblock masterbatch (preferably using Natureworks PLA4060D amorphous PLA as the carrier resin) of ca. 6-10% by weight of layer (C). If the antiblock masterbatch is a 5 wt % antiblock loading, the amount of antiblock in the (C) layer is about 0.3-0.5 wt % or 3000-5000 ppm. A nominal 3 μm spherical sodium calcium aluminum silicate is preferred such as Mizusawa Silton JC30. A suitable antiblock loading in layer (C) is 3000 ppm.

Optionally, in reference to U.S. Provisional Patent application No. 61/218,846, modifiers may be added to the amorphous PLA heat seal layer (C) for improvement of heat seal initiation. These include poly(butylene adipate-co-butylene-terephthalate) (PBAT) or polycaprolactone (PCL) or blends thereof. PBAT is an aromatic copolyester based on terephthalic di-acid and is currently sourced from petroleum-based feedstocks (although it is contemplated that eventually the monomers for PBAT could be sourced from renewable plant-based feedstocks). It has been shown in the literature to be biodegradable and compostable in a micro-organism environment (e.g. compost) with no indication for an environmental risk (i.e. ecotoxicity). PBAT typically has a melting point of about 110-120° C., density of about 1.21, glass transition temperature of about −30° C., a crystallinity of about 20-35%, and a biodegradation mineralization (per 60 days in compost substantially in accordance with ASTM 5336) of 100%. PBAT materials can be obtained commercially from BASF Corporation under the tradename Ecoflex®. In particular, Ecoflex® 7011 grade is preferred with a melting point of about 119° C., melt flow index of about 3.0 g/10 min at 190° C., density of about 1.25-1.27, Shore D hardness of about 32, and Vicat softness of about 91° C. Other PBAT resins may be obtained from DuPont's Biomax® series of resins or Novamont's Origo-bi™ series of resins.

Another suitable modifying resin to improve further the heat seal initiation properties of amorphous PLA is polycaprolactone. PCL is a polyester produced by the ring-opening of e-caprolactone in the presence of aluminum isopropoxide and is currently sourced from petroleum-based monomers. According to the literature, PCL has been shown to undergo hydrolysis and biodegradation by fungi and can be easily enzymatically degraded. PCL typically has a melting temperature of about 65° C., a glass transition temperature of about −61° C., a density of about 1.11, a crystallinity of about 67%, and a biodegradation mineralization (per 60 days in compost substantially in accordance with ASTM 5336) of 100%. PCL can be obtained from Perstorp Specialty Chemicals Group under the tradename CAPA®. In particular, the CAPA® 6000 PCL resin series is preferred, such as CAPA® 6500 (melting point about 58-60° C., mean molecular weight about 50,000, melt flow index about 7 g/10 min at 160° C.); CAPA® 6800 (melting point about 58-60° C., mean molecular weight about 80,000, melt flow index about 3 g/10 min at 160° C.); CAPA® 6FB100 (melting point about 58-60° C., mean molecular weight about 100,000, melt flow index about 4 g/10 min at 190° C.). Particularly preferred is the CAPA® 6500 grade which may be easier to process with amorphous PLA in extrusion equipment than the other grades. PCL can also be obtained from Danimer Scientific LLC grades 28709 and 28710 which have a melting point of about 56-57° C., density of about 1.12, and melt flow rate of about 1.0-1.5 g/10 min at 190° C. Danimer Scientific also can provide a grade that is comprised of a blend of PLA and PCL: Grade 26806 with a bi-modal melting point of about 150° C. and 57° C. (reflective of the PLA/PCL blend), density of about 1.12, and melt flow rate of about 1.9 g/10 min at 190° C.

Suitable amounts of these modifying resins for improving the amorphous PLA heat seal properties are about 1-50 wt % of the heat sealable layer. Preferably, the amount is about 5-30 wt %, and even more preferably, 10-20 wt %. In particular, if PCL is used, preferably the amount used is about 10-20 wt % of the heat sealable layer; if PBAT is used, preferably the amount used is about 10-30 wt % of the heat sealable layer. When using the PBAT additive with the amorphous PLA heat seal resin, it is recommended to use a compatibilizer to improve the dispersion and miscibility of the PBAT in the amorphous PLA; however, this is an optional component. A suitable compatibilizer is BASF Corporation's Joncryl® ADR4368CS styrene acrylic copolymer (molecular weight about 6800 and glass transition temperature of about 54° C.) in an amount of 0.03 wt % to 0.9 wt % of the sealant layer, preferably, 0.15 wt % to 0.45 wt %. It could also be contemplated to use blends of PCL and PBAT in combination with the amorphous PLA to improve heat seal initiation temperature.

The heat sealable resin layer (C) can be coextruded on either side of the core layer, said heat sealable layer having a thickness after biaxial orientation of between 0.5 and 5 μm, preferably between 1.0 and 2.0 μm.

The skin layer (A) can be surface-treated if desired with a corona-discharge method, flame treatment, atmospheric plasma, or corona discharge in a controlled atmosphere of nitrogen, carbon dioxide, or a mixture thereof which excludes oxygen. The latter treatment method in a mixture of CO₂ and N₂ only is preferred. This method of discharge treatment results in a treated surface that comprises nitrogen-bearing functional groups, preferably 0.3% or more nitrogen in atomic %, and more preferably 0.5% or more nitrogen in atomic %. This discharge-treated surface can then be metallized, printed, coated, or extrusion or adhesive laminated. Preferably, it is printed or metallized, and more preferably, metallized.

The multilayer coextruded film can be made either by sequential biaxial orientation or simultaneous biaxial orientation, which are well-known processes in the art. In the case of sequential orientation, a 1.5-meter wide sequential orientation film-making line was used. The multilayer coextruded laminate sheet is coextruded at processing temperatures of ca. 190° C. to 205° C. through a die and cast onto a cooling drum whose surface temperature is controlled between 15° C. and 26° C. to solidify the non-oriented laminate sheet at a casting speed of about 6 mpm. The non-oriented laminate sheet is stretched in the longitudinal direction at about 55° C. to 65° C. at a stretching ratio of about 3 to about 4 times the original length. The resulting stretched sheet is annealed at about 40° C. to 45° C. and cooled at about 30° C. to 40° C. to obtain a uniaxially oriented laminate sheet. The uniaxially oriented laminate sheet is introduced into a tenter at a linespeed of ca. 18 to 50 mpm and preliminarily heated between about 65° C. and 75° C., and stretched in the transverse direction at about 75° C. to 90° C. at a stretching ratio of about 4 to about 8 times the original length and then heat-set or annealed at about 90° C. to 95° C. with the exit rails set for about a 5% relaxation to reduce internal stresses due to the orientation and minimize shrinkage and give a relatively thermally stable biaxially oriented sheet.

After biaxial orientation, the thickness of the coextruded film overall is nominal 75G (18.75 μm), the skin layer (A) is nominal 4G (1 μm), the sealant layer (C) is nominal 8G (2.0 μm), and the core layer is nominal 63G (15.75 μm). The film is heat-set or annealed in the final zone of the tenter oven to reduce internal stresses, minimize heat shrinkage of the film, and maintain a dimensionally stable biaxially oriented film. The metal receiving layer (A) surface on the side of the core layer opposite the sealable layer (C) is treated via corona discharge treatment method after orientation. The BOPLA multi-layer film is wound in roll form. It is contemplated to process further the film such as metallizing the treated surface of the film to produce metallized barrier films, coating the treated surface of the film for other properties, or utilizing the treated surface for printing or laminating.

A preferable embodiment is to metallize the discharge-treated skin layer. The unmetallized laminate sheet is first wound in a roll. The roll is placed in a vacuum metallizing chamber and the metal is vapor-deposited onto the (optionally, but preferably) discharge-treated metal receiving layer surface. The metal film may include titanium, vanadium, chromium, manganese, iron, cobalt, nickel, copper, zinc, aluminum, gold, or palladium, the preferred being aluminum. Metal oxides can also be contemplated, the preferred being aluminum oxide. The metal layer can have a thickness between 5 and 100 nm, preferably between 20 and 80 nm, more preferably between 30 and 60 nm; and an optical density between 1.5 and 5.0, preferably between 2.0 and 4.0, more preferably between 2.2 and 3.2. The metallized film is then tested for oxygen and moisture gas permeability, optical density, metal adhesion, metal appearance and gloss, heat seal performance, tensile properties, thermal dimensional stability, and can be made into a laminate structure.

Optionally, prior to aluminum deposition within the metallizing vacuum chamber, the film can be pre-treated using a type of sputtering with a copper cathode at a linespeed of about 305 mpm. This treater is typically set up in the low vacuum section of the metallizer where the unwinding roll is located and the film is passed through this treater prior to entering the high vacuum section of the metallizer where the evaporation boats are located. The treater uses high voltage between the anode and cathode to produce free electrons. Oxygen gas is introduced into the treater and the free electrons combine with the oxygen gas to produce oxygen ions. Magnetic fields guide and accelerate the oxygen ions onto the copper cathode target which then emit copper ions. These copper ions are deposited onto the PHA-containing resin skin layer substrate, creating a monolayer of copper, ca. 20 ng/m² (nanogram/sq. meter) thick. The film is then passed into the high vacuum deposition chamber of the metallizer, which is metallized using aluminum to a nominal optical density target of 2.4. Optical densities for aluminum deposition can range from 2.0 to 5.0. The metallized rolls were then slit on a film slitter and tested for properties. This process may be beneficial to improve metal adhesion and gas barrier properties further as the copper ion deposition prior to other metal deposition acts as a “primer” for the subsequent metal deposition such as aluminum. This process is described in U.S. patent application Ser. No. 12/542,428 and this reference is incorporated herein in its entirety.

It should be noted that in the case where this in-chamber “treating” method is used, it is preferable that the incoming unmetallized basefilm roll remains untreated from the film-making line such that said basefilm experiences only one exposure to discharge-treatment processes. This will help avoid possible or potential degradation of the substrate's surface, which might result in low metal adhesion properties due to a surface layer of low molecular weight degradation material.

This invention will be better understood with reference to the following examples, which are intended to illustrate specific embodiments within the overall scope of the invention. In the Examples, the metal receiving layer skin (A) is comprised of several different compositions.

### Comparative Example 1

A three-layer coextruded biaxially oriented PLA film was made using sequential orientation on a 1.5-meter wide tenter frame line as described previously, comprising a non-sealable skin layer (A) formulation of about 85 wt % Natureworks PLA4032D and 15 wt % PLA4060D. The core layer (B) was comprised of about 82 wt % PLA4032D with about 15 wt % PLA4060D and 3 wt % Biomax 120. The coextruded heat sealable layer (C) is comprised substantially of about 94 wt % PLA4060D with about 6 wt % of a JC30 antiblock masterbatch such that the concentration of antiblock in the layer (C) is about 3000 ppm (0.3 wt %).

The total thickness of the film substrate after biaxial orientation is ca. 75G (18.75 μm). The thickness of the skin layer (A) after biaxial orientation was ca. 4G (1 μm). The thickness of the sealant layer (C) after biaxial orientation was ca. 8G (2.0 μm). The thickness of the core layer was ca. 63G (15.75 μm). The skin layers and the core layer were melt coextruded together through a flat die to be cast on a chill drum using an electrostatic pinner. The formed cast sheet was passed through a machine-direction orienter to stretch in the machine direction (MD) at ca. 3.0× stretch ratio in the longitudinal direction. This was followed by transverse direction (TD) stretching at ca. 8× stretch ratio in the tenter oven. The resultant biaxially oriented film was subsequently heat-set and discharge-treated on the skin layer (A)'s surface opposite said heat sealable skin layer (C) via corona treatment. The film was then wound up in roll form and metallized with aluminum via vapor deposition (as described previously) to an optical density of nominal 2.4.

### Example 1

A process similar to Comparative Example 1 (CEx 1) is followed except that the metal receiving layer (A) is changed to substantially 100 wt % of PHBV resin Tiannan Enmat 5010P.

### Example 2

A process similar to CEx 1 is followed except that layer (A) is changed to about 50 wt % PHBV and 42.5 wt % PLA4032D and 7.5 wt % PLA4060D.

### Example 3

A process similar to CEx 1 is followed except that layer (A) is changed to about 20 wt % PHBV, 68 wt % PLA4032D, and 12 wt % PLA4060D.

### Example 4

A process similar to CEx 1 was followed except that layer (A) is changed to substantially 100 wt % PHB resin from Metabolix Mirel.

The BOPLA-PHA metallized films are then tested for oxygen transmission rate (O₂TR), moisture vapor transmission rate (MVTR), metal adhesion, and appearance.

The following Table 3 illustrates the properties of these examples:

TABLE 3

| | | | | | | | Appearance (1-4, |
|---|---|---|---|---|---|---|---|
| | Example Layer Composition (wt % of layer) | | | MVTR | O2TR | Metal Adh. | 4 = best, |
| Sample | Layer A | Layer B | Layer C | g/m²/day | cc/m²/day | (g/in) | 1 = poor) |
| CEx. 1 | PLA4032D (85%) | PLA 4032D (82%) | PLA4060D (94%) | 1.24 | 14.0 | 50 | 4 |
| | PLA4060D (15%) | PLA4060D (15%) | JC30MB (6%) | | | | |
| | | Biomax 120 (3%) | | | | | |
| Ex. 1 | PHBV (100%) | same as CEx 1 | same as CEx 1 | 0.69 | 14.9 | 57 | 3 |
| Ex. 2 | PHBV (50%) | Same as CEx 1 | same as CEx 1 | 0.75 | 11.9 | 73 | 3 |
| | PLA4032D (42.5%) | | | | | | |
| | PLA4060D (7.5%) | | | | | | |
| Ex. 3 | PHBV (20%) | same as Cex 1 | same as CEx 1 | 0.93 | 30.1 | 82 | 3 |
| | PLA4032D (68%) | | | | | | |
| | PLA4060D (12%) | | | | | | |
| Ex. 4 | PHB(100%) | same as Cex 1 | same as CEx 1 | 0.78 | — | 35 | 3 |

As Table 1 shows, Comparative Example 1 (CEx 1) was a control film using PLA at 97 wt % of the core layer (B) and 100 wt % of the metal receiving layer (A). Its metal appearance was good and barrier properties and metal adhesion tested as shown.

Examples 1 to 3 used the same core and heat seal blend formulation as CEx 1 but the metal receiving layer (A) used various blends of PHBV and PLA. Examples 1 to 3 showed an improvement in moisture barrier using at least 20 wt % to 100 wt % of the EnMat PHBV blended with PLA after metallization compared to CEx 1 which has no PHBV blended with the PLA metal receiving layer. Metal adhesion, metal appearance, and oxygen barrier was fit-for-use.

Example 4 uses the same core and heat seal blend formulation as CEx1. The metal receiving layer (A) is changed to Metabolix PHB resin. As with Examples 1 to 3, an improvement in moisture barrier was observed; metal adhesion, however, was lower than previous samples. Metal appearance was still acceptable.

### Test Methods

The various properties in the above examples are measured by the following methods:

Heat seal strength is measured by using a Sentinel sealer model 12 ASL at 30 psi, 0.5 second dwell time, with heated flat upper seal jaw Teflon coated, and unheated lower seal jaw, rubber with glass cloth-covered. The film is heat-sealed sealant-side to sealant-side at the desired seal temperature range and increments in the Sentinel sealer (e.g. 180-290° F. at 10° F. increments) and then the respective seal strengths are measured using an Instron model 4201 tensile tester. The heat-sealed samples are cut into 1-inch wide strips, the two unsealed tails are placed in the upper and lower Instron clamps and the sealed tail supported at a 90° angle to the two unsealed tails for a 90° T-peel test. The peak and average seal strength are recorded. The preferred values for acceptable heat seal strength are 400 g/in or greater at 250° F. seal temperature.

Hot tack strength is measured by using a Lako Tool hot tack/sealer model SL10 at 30 psi, 0.5 second dwell time, with heated flat lower seal jaw Teflon coated, and unheated upper seal jaw and with delay set to 0 seconds. The film sample is cut into a strip 13 inches long by 1 inch wide and fitted into the Lako SL10 film holder. The film is then heat-sealed sealant-side to sealant-side at the desired seal temperature range and increments in the Lako sealer (e.g. 180-290° F. at 10° F. increments) and then the respective hot tack strengths are measured by the Lako SL10 sealer automatically. The peak hot tack strength is recorded. The preferred value for acceptable hot tack is 150 g/in or greater at 250° F. seal temperature.

Heat seal and hot tack seal initiation temperature (SIT) is measured by using the above methods (A) and (B) using the Sentinel 12 ASL or Lako Tool SL10 hot tack sealer. Heat seal initiation temperature is the lowest temperature at which minimum 200 g/in seal strength is achieved. Hot tack initiation temperature is the lowest temperature at which minimum 150 g/in hot tack is achieved. Initiation temperatures of 200° F. or less are preferred.

Transparency of the film is measured by measuring haze of a single sheet of film substantially in accordance with ASTM D1003.

Moisture transmission rate of the film is measured by using a Mocon Permatran 3/31 unit substantially in accordance with ASTM F1249. A hand-lamination was made of the metallized PLA film using a 5.5-mil (137.5 μm) cast LDPE film with a pressure-sensitive adhesive (available from Berry Plastics, Inc. 502A clear LDPE tape with acrylic-based pressure sensitive adhesive) in order to protect the metallized film surface from handling damage. The pressure-sensitive adhesive side of the LDPE film would be adhered to the metallized side of the example film with a rubber roller to eliminate air pockets, bubbles, and wrinkles. In general, preferred values of MVTR would be less than 1.0 g/m²/day and preferably 0.5 g/m²/day or less at 100° F. and 90% relative humidity.

Oxygen transmission rate of the film is measured by using a Mocon Oxtran 2/20 unit substantially in accordance with ASTM D3985. A hand-lamination was made of the metallized PLA film using a 5.5-mil (137.5 μm) cast LDPE film with a pressure-sensitive adhesive (available from Berry Plastics, Inc. 502A clear LDPE tape with acrylic-based pressure sensitive adhesive) in order to protect the metallized film surface from handling damage. The pressure-sensitive adhesive side of the LDPE film would be adhered to the metallized side of the example film with a rubber roller to eliminate air pockets, bubbles, and wrinkles. In general, preferred values of O₂TR would be equal to or less than 46.5 cc/m²/day at 73° F. and 0% relative humidity.

Metal adhesion is measured by heat sealing on a SENTINAL Sealer model 12 ASL at 220° F. (104.4° C.) seal temperature, 15 second dwell, and 15 psi (103.42 kPa) seal jaw pressure, a piece of 1-mil (25 μm) thick Ethylene Acrylic Acid polymer film (EAA) to the metallized surface of a single sheet of metallized film and measuring the 180° peel strength of the metal from the substrate substantially in accordance with AIMCAL (Association of Industrial Metallizers, Coaters, and Laminators) test procedure TP-105-92. The test procedure and a kit of materials can be obtained from AIMCAL's website www.aimcal.com. The Metal Adhesion Test Kit is designed to permit testing using TP-105-92. The test kit contains 2 rolls of 3M™ tape #610, 2 rolls of EAA film and an AIMCAL Metallizing Technical Reference Manual. The test kit contains enough material to do at least 100 tests as described in the Technical Reference Manual, (TP-105-92). The test procedure used in testing the samples used in the examples of this application is described in AIMCAL Metallizing Technical Reference (Third Edition, © 2001). In general, the preferred value of metal adhesion ranges from about 50 g/in (50 g/25 mm) minimum or higher.

Metal appearance is rated qualitatively using a ranking system of 1-4, with 1 equating to a very matte or high density of defects (e.g. die lines, gels, etc) metallized film appearance and 4 equating to a very shiny, glossy, reflective, defect-free metallized film appearance. 8½″×11″ cut sheet samples of the metallized films are observed on a white background under office fluorescent lighting, and ranked in order of metal shininess. The rating is “calibrated” using control films CEx 1 as a “4”.

This application discloses several numerical ranges in the text and figures. The numerical ranges disclosed inherently support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

What is claimed as new and desired to be protected by Letters Patent of the United States is:

1. A biaxially oriented film comprising:
a skin layer comprising a polyhydroxyalkanoate-containing resin; and
a core layer comprising a polylactic acid polymer.

2. The film of claim 1, wherein the skin comprises poly(3-hydroxy-butyrate-co-3-hydroxyvalerate), polyhydroxybutyrate, or polyhydroxyalkanoate.

3. The film of claim 2, wherein the skin layer further comprises crystalline or amorphous polylactic acid.

4. The film of claim 1, wherein the skin layer comprises at least 20 wt % polyhydroxyalkanoate-containing resin.

5. The film of claim 1, wherein the skin layer comprising a polyhydroxyalkanoate-containing resin is discharge treated.

6. The film of claim 1, further comprising a metal layer on the skin layer comprising a polyhydroxyalkanoate-containing resin.

7. The film of claim 6, wherein the metal layer is aluminum.

8. The film of claim 6, wherein the metal layer has an optical density of 1.5 to 5.0.

9. The film of claim 1, further comprising a sealant layer on a side of the core layer opposite the skin layer comprising a polyhydroxyalkanoate-containing resin.

10. The film of claim 9, wherein the sealant layer comprises an amorphous polylactic acid polymer.

11. The film of claim 1, wherein the core layer comprises crystalline polylactic acid polymer.

12. The film of claim 11, wherein the core layer further comprises amorphous polylactic acid polymer.

13. A method of making a multilayer film comprising:
co-extruding a film comprising a core layer comprising a polylactic acid polymer, and a skin layer comprising a polyhydroxyalkanoate-containing resin; and
biaxially orienting the film.

14. The method of claim 13, wherein the skin comprises poly(3-hydroxy-butyrate-co-3-hydroxyvalerate), polyhydroxybutyrate, or polyhydroxyalkanoate.

15. The method of claim 14, wherein the skin layer further comprises crystalline or amorphous polylactic acid.

16. The method of claim 13, wherein the skin layer comprises at least 20 wt % polyhydroxyalkanoate-containing resin.

17. The method of claim 13, wherein the skin layer comprising a polyhydroxyalkanoate-containing resin is discharge treated.

18. The method of claim 13, further comprising vapor-depositing a metal layer on the skin layer comprising a polyhydroxyalkanoate-containing resin.

19. The method of claim 18, wherein the metal layer is aluminum.

20. The method of claim 19, wherein the metal layer has an optical density of 1.5 to 5.0.

21. The method of claim 13, further comprising co-extruding a sealant layer on a side of the core layer opposite the skin layer comprising a polyhydroxyalkanoate-containing resin.

22. The method of claim 21, wherein the sealant layer comprises an amorphous polylactic acid polymer.

23. The method of claim 13, wherein the core layer comprises crystalline polylactic acid polymer.

24. The method of claim 23, wherein the core layer further comprises amorphous polylactic acid polymer.
